(19) United States
(12) Patent Application Publication
(10) Pub. No.: US 2025/0226769 A1
(43) Pub. Date: Jul. 10, 2025

(54) POWER CONVERSION DEVICE AND REFRIGERATION CYCLE APPLIED EQUIPMENT

(71) Applicant: Mitsubishi Electric Corporation, Tokyo (JP)

(72) Inventors: Takaaki TAKAHARA, Tokyo (JP); Koichi ARISAWA, Tokyo (JP); Haruka MATSUO, Tokyo (JP); Tomohiro KUTSUKI, Tokyo (JP); Yusuke MORIMOTO, Tokyo (JP); Yuya KONDO, Tokyo (JP)

(21) Appl. No.: 18/698,896

(22) PCT Filed: Nov. 12, 2021
(86) PCT No.: PCT/JP2021/041676

§ 371 Date: Apr. 5, 2024

(51) Int. Cl. H02M 7/5387; F25B 31/02; H02M 1/34; H02M 5/458; H05K 7/20

(52) U.S. Cl. CPC H02M 7/5387; F25B 31/026; H02M 1/346; H02M 5/4585; H05K 7/209

(57) ABSTRACT

A power conversion device includes rectifier circuitry that rectifies a first alternating current supplied from a power source and outputs a first current, which is the rectified current, a smoothing capacitor connected between the output terminals of the rectifier circuitry, an inverter including input terminals, converting a second current, which is a current of the first current input to the input terminals, into a second alternating current, and outputting the second current, a snubber capacitor connected between the input terminals in the proximity of the input terminals, and a controller that controls the inverter so that the second alternating current includes pulsation corresponding to pulsation of the second current.

### CROSS-REFERENCE TO RELATED APPLICATION

This application is a U.S. national stage application of PCT/JP2021/041676 filed Nov. 12, 2021, the contents of which are incorporated herein by reference.

### TECHNICAL FIELD

The present disclosure relates to a power conversion device and refrigeration cycle applied equipment.

### BACKGROUND

A power conversion device that includes a diode stack that is rectifier circuitry that rectifies an alternating current, a smoothing capacitor that smoothes the voltage of the rectified current, and an inverter that generates an alternating current for driving an electric motor from the rectified current has been proposed (see, e.g., Patent Reference 1).

### PATENT REFERENCE

Patent Reference 1: Japanese Unexamined Patent Application Publication No. H07-71805 (see, e.g., FIG. 1, paragraphs 0031-0032)

In conventional power conversion device described above, a surge component is superimposed on the current input to the inverter (e.g., its pulsating current), which may cause a failure in a switching element that composes the inverter.

### SUMMARY

To solve the above problem, it is an object of the present disclosure to provide a power conversion device and refrigeration cycle applied equipment capable of reducing a surge component.

A power conversion device according to the present disclosure includes: rectifier circuitry to rectify a first alternating current supplied from a power source and to output a first current as a rectified current; a smoothing capacitor connected between output terminals of the rectifier circuitry; an inverter including input terminals, to convert a second current in the first current into a second alternating current, and to output the second alternating current, the second current being a current inputted to the input terminals; a snubber capacitor connected between the input terminals at a position in the proximity of the input terminals; and a controller to control the inverter so that pulsation in AC power output from the inverter is smaller than pulsation of power output from the rectifier circuitry.

Refrigeration cycle applied equipment according to the present disclosure includes: a power conversion device; and a refrigeration cycle device including an electric motor driven by the power conversion device.

According to the present disclosure, a surge component of the current input to the inverter can be reduced.

### BRIEF DESCRIPTION OF THE DRAWINGS

FIG. 1 is a diagram showing an example of the configuration of a power conversion device that performs inverter control using pulsation.

FIG. 2 is a diagram showing Example 1 of each current and the capacitor voltage of a smoothing capacitor when the current output from a rectifier is smoothed at the smoothing capacitor and the current flowing into an inverter is kept constant.

FIG. 3 is a diagram showing Example 2 of each current and the capacitor voltage of the smoothing capacitor when a controller controls the operation of the inverter so that the current that flows into the smoothing capacitor is reduced.

FIG. 4 is a diagram schematically showing the configuration of a power conversion device according to a first embodiment.

FIG. 5 is a diagram schematically showing the configuration of the inverter.

FIG. 6 is a diagram showing Example 3 of each current and the capacitor voltage of the smoothing capacitor when the controller controls the operation of the inverter so that the current that flows into the smoothing capacitor is reduced.

FIG. 7 is a waveform diagram showing the surge voltage in the case of a comparative example (without snubber capacitor) and the surge voltage in the case of the first embodiment (with snubber capacitor).

FIG. 8 is a diagram showing an example of the configuration of a power conversion device according to a modification of the first embodiment.

FIG. 9A shows the waveforms for the case without PFC, and FIG. 9B shows the waveforms for the case with PFC.

FIG. 10A is a side surface view showing the location of a snubber capacitor of a power conversion device according to a second embodiment, FIG. 10B is a side surface view showing a fixing member for the snubber capacitor, and FIG. 10C is a front view showing the fixing member for the snubber capacitor.

FIG. 11A is a side surface view showing the location of a snubber capacitor of a power conversion device according to a third embodiment, and FIG. 11B is a side view showing a vibration damping member that is a fixing member for the snubber capacitor.

FIG. 12A is a side surface view showing the location of a snubber capacitor of a power conversion device according to a fourth embodiment, and FIG. 12B is a cross-sectional view showing the wiring layer that constitutes part of the snubber capacitor.

FIG. 13 is a diagram showing the configuration of an air conditioner as refrigeration cycle applied equipment according to a fifth embodiment.

### DETAILED DESCRIPTION

A power conversion device and refrigeration cycle applied equipment according to embodiments will be described below with reference to the drawings. The following embodiments are merely examples. It is possible to combine the embodiments as appropriate and to change each embodiment as appropriate. In the description hereafter, first, “inverter control using pulsation,” which is the premise technology of the embodiments, is explained, and then “embodiments 1 to 5” using “inverter control using pulsation” are described.

### Inverter Control Using Pulsation

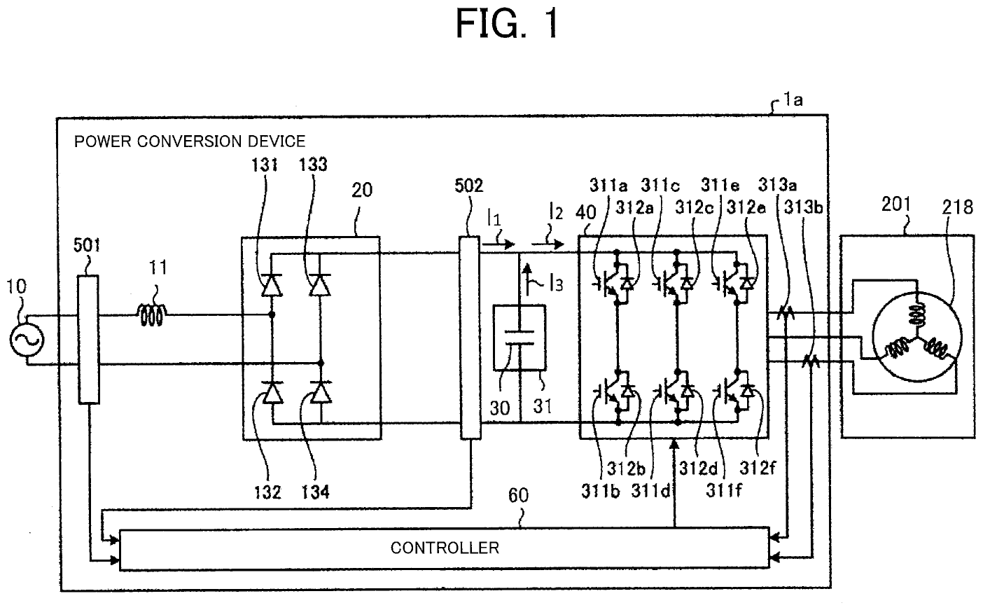

FIG. 1 is a diagram showing an example of the configuration of a power conversion device 1a that performs inverter control using pulsation. The power conversion device 1a is connected to a power source (e.g., commercial power source) 10 and a compressor 201. The power conversion device 1a converts a first AC power of the power supply voltage Vs supplied from the power source 10 into a second AC power having the desired amplitude and phase, and supplies the second AC power to the compressor 201. The power conversion device 1a includes a voltage/current detector 501, a reactor 11, a rectifier 20 that is rectifier circuitry, a voltage detector 502, a smoothing unit 31 composed of a smoothing capacitor 30, an inverter 40, current detectors 313a and 313b, and a controller 60. It should be noted that the power conversion device 1a is a motor drive device that drives the electric motor 208.

The voltage/current detector 501 detects the voltage value and current value of the first AC power of the power supply voltage Vs supplied from the power source 10 and outputs the detected voltage value and current value to the controller 60. The reactor 11 is connected, for example, between the voltage/current detector 501 and the rectifier 20. The rectifier 20 includes bridge circuitry composed of rectifier elements (diodes) 131 to 134, and rectifies and outputs the first AC power of the power supply voltage Vs supplied from the power source 10. The rectifier 20 is a full-wave rectifier. The voltage detector 502 detects the voltage value of the power rectified by the rectifier 20 and outputs the detected voltage value to the controller 60. The smoothing unit 31 is connected to the output terminal of the rectifier 20 through the voltage detector 502. The smoothing unit 31 includes a smoothing capacitor 30 as a smoothing element and smoothes the power rectified by the rectifier 20. The smoothing capacitor 30 is, for example, an electrolytic capacitor or a film capacitor. The smoothing capacitor 30 has a capacity such that the power rectified by the rectifier 20 is smoothed. The voltage generated in the smoothing capacitor 30 by the smoothing does not form the full-wave rectified waveform shape of the power source 10, but form a waveform shape in which a voltage ripple is superimposed on the DC component depending on the frequency of the power source 10, and does not pulsate greatly. The frequency of this voltage ripple is a twofold component of the frequency of the power supply voltage Vs when the power source 10 is single-phase, and a six-fold component is the main component when the power source 10 has three-phase. If the power input from the power source 10 and the power output from the inverter 40 are unchanged, the amplitude of this voltage ripple depends on the capacitance of the smoothing capacitor 30. For example, the voltage ripple pulsates in a range such that the maximum value of the voltage ripple generated in the smoothing capacitor 30 is less than twice the minimum value.

The inverter 40 is connected to both ends of the smoothing capacitor 30 (i.e., both ends of the smoothing unit 31). The inverter 40 includes switching elements 311a-311f and reflux diodes 312a-312f. The inverter 40 is controlled by the controller 60 to turn on and off the switching elements 311a-311f, converts the power output from the rectifier 20 and the smoothing capacitor 30 into a second AC power with a desired amplitude and phase, and outputs the power to the compressor 201. The current detectors 313a and 313b each detect the current value of one of the three-phase currents output from the inverter 40 and output the detected current value to the controller 60. It should be noted that the controller 60 can calculate the current value of the remaining one phase output from the inverter 40 by obtaining the current values of two of the three-phase currents output from the inverter 40. The compressor 201, which includes the electric motor 208 for compressor drive, serves as a load. The electric motor 208 rotates according to the amplitude and phase of the second AC power supplied from the inverter 40 to perform a compression operation. For example, if the compressor 201 is a sealed compressor used in an air conditioner etc., the load torque of the compressor 201 can often be considered as a constant torque load.

It should be noted that, in the power conversion device 1a, the arrangement of each configuration shown in FIG. 1 is an example, and the arrangement of each configuration is not limited to the example shown in FIG. 1. For example, the reactor 11 may be disposed downstream from the rectifier 20. In the following description, the voltage/current detector 501, the voltage detector 502, and the current detectors 313a and 313b may be referred to collectively as a detector. Also, the voltage and current values detected by the voltage/current detector 501, the voltage value detected by the voltage detector 502, and the current values detected by the current detectors 313a and 313b may be referred to as detected values.

The controller 60 obtains the voltage and current values of the first AC power of the power supply voltage Vs from the voltage/current detector 501, the voltage value of the power rectified by the rectifier 20 from the voltage detector 502, and the current value of the second AC power with the desired amplitude and phase converted by the inverter 40 from the current detectors 313a and 313b. The controller 60 controls the operation of the inverter 40, specifically the on/off of the switching elements 311a-311f of the inverter 40, using the detected value detected by each detector. In the present example, the controller 60 controls the operation of the inverter 40 so that the inverter 40 outputs the second AC power, which includes pulsation corresponding to the pulsation of the power flowing from the rectifier 20 into the smoothing capacitor 30, to the compressor 201 that is a load. The pulsation corresponding to the pulsation of the power flowing into the smoothing capacitor 30 is, for example, pulsation that varies according to the frequency etc. of the pulsation of the power flowing into the smoothing capacitor 30. In this manner, the controller 60 suppresses the current that flows into the smoothing capacitor 30. It should be noted that the controller 60 does not have to use all the detected values obtained from each detector, but may use some of the detected values for control.

Next, the operation of the controller 60 of the power conversion device 1a will be described. In the present example, the load generated by the inverter 40 and the compressor 201 can be regarded as a constant load in the power conversion device 1a. When viewed in terms of the current output from the smoothing capacitor 30, the following description is based on the assumption that a constant current load is connected to the smoothing capacitor 30. Let a current I₁ be a current flowing from the rectifier 20, a current I₂ be a current flowing to the inverter 40, and a current I₃ be a current flowing from the smoothing capacitor 30, as shown in FIG. 1. The current I₂ is the combined current of the current I₁ and the current I₃. The current I₃ can be expressed as the difference between the current I₂ and the current I₁, i.e., current I₂−current I₁. The current I₃ is positive in the discharging direction of the smoothing capacitor 30 and negative in the charging direction of the smoothing capacitor 30. In other words, a current may flow into and flow from the smoothing capacitor 30.

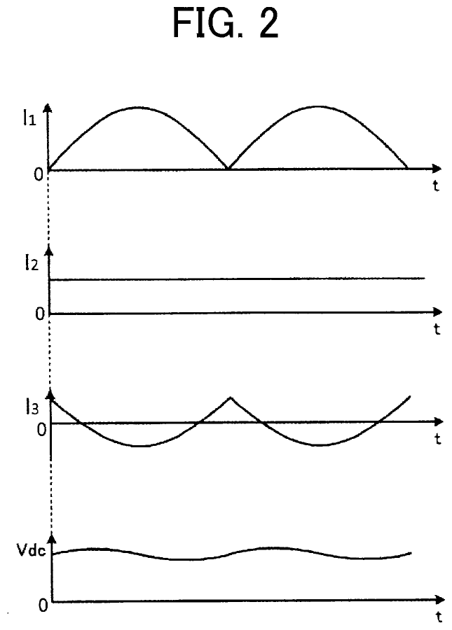

FIG. 2 is a diagram showing an example of each current I₁ to I₃ and the capacitor voltage Vdc of the smoothing capacitor 30 when the current output from the rectifier 20 is smoothed at the smoothing capacitor 30 and the current I₂ flowing into the inverter 40 is kept constant, as Example 1. From top to bottom, the current I₁, the current I₂, the current I₃, and the capacitor voltage Vdc of the smoothing capacitor 30 that occurs according to the current I₃ are shown. The vertical axes of the currents I₁, I₂, and I₃ show current values [A], and the vertical axis of the capacitor voltage Vdc shows voltage values [V]. The horizontal axes all indicate time t. It should be noted that the carrier component of the inverter 40 is actually superimposed on the currents I₂ and I₃, but details are omitted in this example. The same applies to the following. As shown in FIG. 2, in the power conversion device 1a, if the current I₁ flowing from the rectifier 20 is sufficiently smoothed by the smoothing capacitor 30, the current I₂ flowing into the inverter 40 becomes a constant current value. However, a large current I₃ flows through the smoothing capacitor 30, which causes deterioration. For that reason, in Example 1, in the power conversion device 1a, the controller 60 controls the current I₂ flowing into the inverter 40, i.e., the operation of the inverter 40, to reduce the current I₃ that flows into the smoothing capacitor 30.

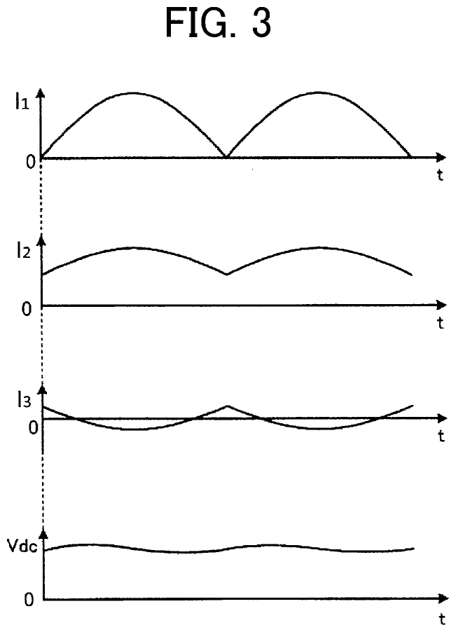

FIG. 3 is a diagram showing an example of each current I₁ to I₃ and the capacitor voltage Vdc of the smoothing capacitor 30 when the controller 60 of the power conversion device 1a controls the operation of the inverter 40 so that the current I₃ that flows into the smoothing capacitor 30 is reduced, as Example 2. From top to bottom, the current I₁, the current I₂, the current I₃, and the capacitor voltage Vdc of the smoothing capacitor 30 that occurs according to the current I₃ are shown. The vertical axes of the currents I₁, I₂, and I₃ show current values [A], and the vertical axis of the capacitor voltage Vdc shows voltage values [V]. The horizontal axes all indicate tire t. The controller 60 of the power conversion device 1a controls the operation of the inverter 40 so that the current I₂ shown in FIG. 3 flows into the inverter 40. Accordingly, compared to the example in FIG. 2, the frequency component of the current that flows from the rectifier 20 into the smoothing capacitor 30 is reduced, and thus the current I₃ that flows into the smoothing capacitor 30 can be reduced. Specifically, the controller 60 controls the operation of the inverter 40 so that the current I₂, which includes a pulsating current with the frequency component of the current I₁ as its main component, flows into the inverter 40.

The frequency component of the current I₁ is determined on the basis of the frequency of the alternating current supplied from the power source 10 and the configuration of the rectifier 20. For that reason, the controller 60 can set the frequency component of the pulsating current superimposed on the current I₂ to a component with a predetermined amplitude and phase. The frequency component of the pulsating current superimposed on the current I₂ forms a waveform similar to the frequency component of the current I₁. The controller 60 brings the frequency component of the pulsating current superimposed on the current I₂ close to the frequency component of the current I₁ and reduces the current I₃ that flows into the smoothing capacitor 30. This makes it possible to reduce the pulsating voltage generated in the capacitor voltage Vdc.

The controller 60 controls the pulsation of the current flowing into the inverter 40 by controlling the operation of the inverter 40, which is the same as controlling the pulsation of the first AC power output from the inverter 40 to the compressor 201. The controller 60 controls the operation of the inverter 40 so that the pulsation in the second AC power output from the inverter 40 is smaller than the pulsation of the power output from the rectifier 20. The controller 60 controls the amplitude and phase of the pulsation of the second AC power output from the inverter 40 so that the voltage ripple of the capacitor voltage Vdc, that is, the voltage ripple generated in the smoothing capacitor 30, is smaller than the voltage ripple generated in the smoothing capacitor 30 for situations where the second AC power output from the inverter 40 does not include pulsation corresponding to the pulsation of the power flowing into the smoothing capacitor 30. Alternatively, the controller 60 controls the amplitude and phase of the pulsation in the second AC power output from the inverter 40 so that the current ripple flowing in and from the smoothing capacitor 30 is smaller than the current ripple generated in the smoothing capacitor 30 for situations where the second AC power output from the inverter 40 does not include the pulsation corresponding to the pulsation of the power flowing into the smoothing capacitor 30. The situation where the second AC power output from the inverter 40 does not include pulsation corresponding to the pulsation of the power flowing into the smoothing capacitor 30 means control as shown in FIG. 2.

It should be noted that the alternating current supplied from the power source 10 is not limited and may be single-phase or three-phase. The controller 60 may determine the frequency component of the pulsating current superimposed on the current I₂ according to the first AC power supplied from the power source 10. Specifically, the controller 60 controls the pulsating waveform of the current I₂, which flows into the inverter 40, into a shape in which a DC component is added to the pulsating waveform whose main component is a frequency component that is twice the frequency of the first AC power when the first AC power supplied from the power source 10 is single-phase, or six times the frequency of the first AC power when the first AC power supplied from the power source 10 is three-phase. The pulsation waveform is, for example, the shape of the absolute value of a sine wave or the shape of a sine wave. In this case, the controller 60 may add at least one frequency component of an integer multiple of the frequency of the sine wave to the pulsating waveform as a predetermined amplitude. Also, the pulsation waveform may be in the form of a square wave or a triangular wave. In this case, the controller 60 may set the amplitude and phase of the pulsating waveform as predetermined values.

The controller 60 may compute the amount of pulsation included in the second AC power output from the inverter 40, using the voltage applied to the smoothing capacitor 30 or the current flowing into the smoothing capacitor 30. Also, the controller 60 may compute the amount of pulsation included in the second AC power output from the inverter 40, using the voltage or current of the first AC power supplied from the power source 10.

The controller 60 can be achieved by, for example, processing circuitry. The processing circuitry may be achieved, for example, by a processor and memory. The processor is, for example, a Central Processing Unit (CPU), a processing unit, an arithmetic unit, a microprocessor, a microcomputer, a processor, a Digital Signal Processor (DSP), or a system LSI (Large Scale Integration). The memory is non-volatile or volatile semiconductor memory, such as Random Access Memory (RAM), Read Only Memory (RCM), and flash memory.

As described above, according to the control in Example 2, in the power conversion device 1a, the controller 60 reduces the current I₃ that flows into the smoothing capacitor 30 by controlling the operation of the inverter 40 on the basis of the detection value obtained from each of the detectors and superimposing the pulsation of the frequency component according to the frequency component of the current I₁ flowing from the rectifier 20 on the current I₂ flowing into the inverter 40. Accordingly, the current I₃ that flows into the smoothing capacitor 30 is reduced, and thus the power conversion device 1a can use the smoothing capacitor 30 with a smaller ripple current tolerance than in the case where the control in Example 2 is not performed. Also, when the power conversion device 1a reduces the pulsation voltage of the capacitor voltage Vdc, the capacity of the smoothing capacitor 30 to be installed can be reduced compared to the case where the control of Example 2 is not performed. For example, when the smoothing unit 31 is composed of a plurality of smoothing capacitors 30, the power conversion device 1a can reduce the number of smoothing capacitors 30 that compose the smoothing unit 31.

Also, according to Example 2, the power conversion device 1a controls the operation of the inverter 40 so that the pulsation in the second AC power is smaller than the pulsation of the power output from the rectifier 20, thereby preventing the pulsation component superimposed on the current I₂ that flows into the inverter 40 from becoming excessive. Although the superimposition of the pulsation component increases the effective value of the current flowing through the inverter 40, electric motor 208, or the like compared to the non-superimposed state, it is possible to provide a system in which the current capacity of the inverter 40, increase in loss of the inverter 40, increase in loss of the electric motor 208, or the like are suppressed by preventing the pulsation component to be superimposed from becoming excessive.

Also, the power conversion device 1a performs the control in Example 2, thereby suppressing the vibration of the compressor 201 caused by the pulsation of the current I₂.

### First Embodiment

### Configuration of First Embodiment

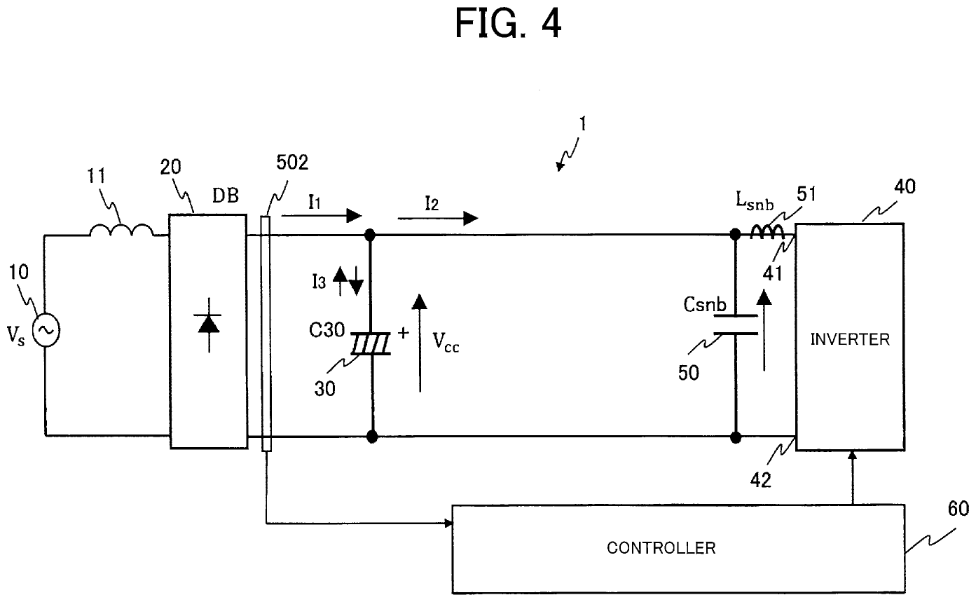

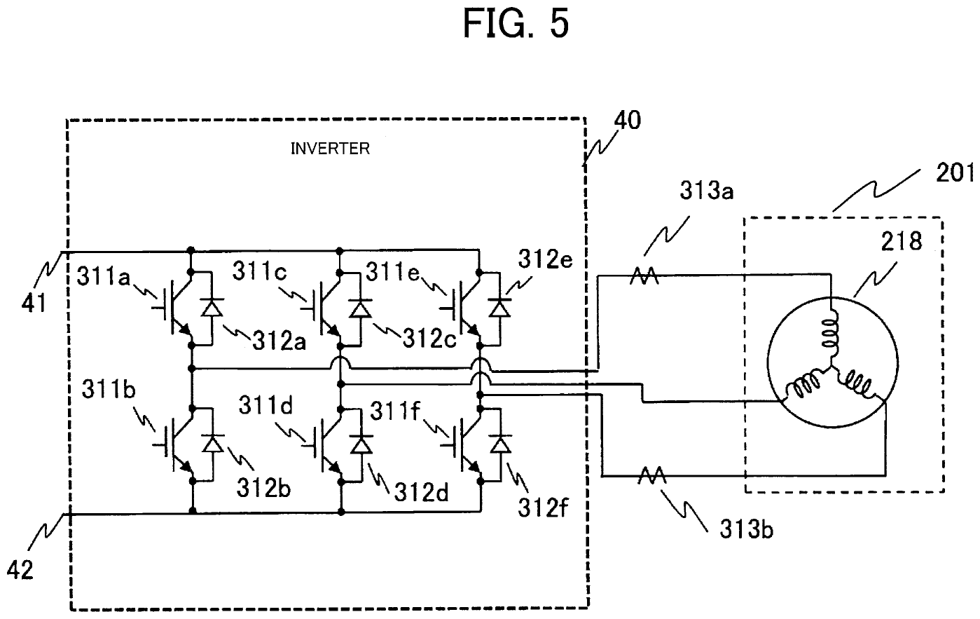

FIG. 4 is a diagram schematically showing the configuration of a power conversion device 1 according to a first embodiment. In FIG. 4, each component identical or corresponding to a component shown in FIG. 1 is assigned the same reference sign as those in FIG. 1. FIG. 5 is a diagram schematically showing the configuration of the inverter 40. In FIG. 5, each component identical or corresponding to a component shown in FIG. 1 is assigned the same reference sign as those in FIG. 1.

The power conversion device 1 includes the rectifier 20 as rectifier circuitry, the smoothing capacitor 30, the inverter 40, a snubber capacitor 50, and the controller 60. The rectifier 20 rectifies the first alternating current supplied from the power source 10 and outputs the rectified current (also referred to as a “first current”) I₁. The smoothing capacitor 30 is connected between the output terminals of the rectifier 20. The inverter 40 includes input terminals 41 and 42, and converts the current (also referred to as a “second current”) I₂, in the current I₁, input to the input terminals 41 and 42 into the second alternating current, and outputs the second alternating current. The snubber capacitor 50 is connected to the input terminals 41 and 42 at a position in the proximity of the input terminals 41 and 42. The proximity position is, for example, direct connection to the input terminals 41 and 42 or connection to the wiring connected between the input terminals 41 and 42. The controller 60 controls the inverter 40 so that the second alternating current includes pulsation corresponding to the pulsation of the current I₂.

Also, when C represents the electrical capacitance [F] of the snubber capacitor 50, Lₛ represents the inductance [H] of the wiring connected to the input terminals 41 and 42, I₂ represents the current [A] output from the inverter 40, V_, represents the surge voltage [V] of the current I₂ output from the inverter 40, and V_{cc} represents the voltage [V] at both ends of the smoothing capacitor 30, it is preferable that the snubber capacitor 50 satisfy the following condition (1).

$$C \geq \frac{{π}^{2} * {L}_{s} * {( {I}_{2} )}^{2}}{2 {π}^{2} * {( {V}_{s u r g e} )}^{2} - 8 {V}_{c c}^{2}} \qquad ( 1 )$$

It is preferable that the impedance of the first circuitry, which is the circuitry from one of the input terminals of the inverter 40 (e.g., input terminal 42) through the snubber capacitor 50 to the other input terminal (e.g., input terminal 41), be smaller than the impedance of the second circuitry, which is the circuitry from one of the input terminals of the inverter 40 (e.g., input terminal 42) through the smoothing capacitor 30 to the other input terminal (e.g., input terminal 41).

### Derivation of Condition (1)

It is known that the following expression (2) is a condition for the snubber capacitor 50 in FIG. 4.

$${C}_{snb} \geq \frac{{L}_{s} * {( {I}_{2} )}^{2}}{{V}_{s u r g e}^{2} - {V}_{c c}^{2}} \qquad ( 2 )$$

Also, the surge voltage V_{surge}, which is the voltage generated by a surge, is expressed in the following expression (3). Lₛ represents the inductance [H] of the wiring connected to the input terminals 41 and 42, and I_{2MAX} represents the maximum input current [A] for situations where the current I₂ is assumed to be a sine wave.

$${V}_{surge} = {L}_{s} * \frac{{dI}_{2 MAX}}{d t} \qquad ( 3 )$$

Expressing I_{2MAX} in terms of the average current I_{2dc}, which is the average value of the current I₂, gives the following expression (4).

$${I}_{2 MAX} = {I}_{2 dc} * \frac{π}{2} \qquad ( 4 )$$

Expression (4) gives the following Expression (5), using the current I₂, which is the effective value of a current.

$${I}_{2} = {I}_{2 dc} * \frac{π}{2 \sqrt{2}} \qquad ( 5 )$$

Expression (1) can be expressed as the following Equation (6).

$${C}_{s n b} \geq \frac{{L}_{s} * {( {I}_{2} )}^{2}}{{( {L}_{s} * \frac{{dI}_{2 MAX}}{dt} )}^{2} - {V}_{c c}^{2}} \qquad ( 6 )$$

Expression (6) can be expressed as the following Expression (7), using Expressions (3) and (5). Expression (7) is the same as Expression (1).

$${C}_{snb} \geq \frac{{L}_{s} ⋆ {( \frac{π}{2 \sqrt{2}} ⋆ {I}_{2} )}^{2}}{{( {L}_{s} ⋆ \frac{\frac{π}{2} ⋆ {dI}_{2 M A X}}{d t} )}^{2} − {V}_{cc}^{2}} = \frac{\frac{{π}^{2}}{8} ⋆ {L}_{s} ⋆ {( {I}_{2} )}^{2}}{\frac{{π}^{2}}{4} ⋆ {( {L}_{s} ⋆ \frac{d {I}_{2 MAX}}{d t} )}^{2} − {V}_{cc}^{2}} = \frac{{π}^{2} ⋆ {L}_{s} ⋆ {( {I}_{2} )}^{2}}{2 {π}^{2} ⋆ {( {V}_{surge} )}^{2} − 8 {V}_{cc}^{2}} \qquad ( 7 )$$

### Operation of First Embodiment

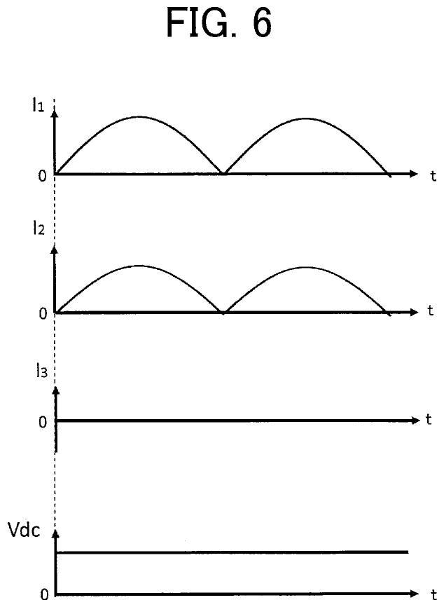

FIG. 6 is a diagram showing an example 3 of each current and the capacitor voltage Vdc of the smoothing capacitor 30 when the controller 60 controls the operation of the inverter 40 so that the current I₃ that flows into the smoothing capacitor 30 is reduced. From top to bottom in FIG. 6, the current I₁, the current I₂, the current I₃, and the capacitor voltage Vdc of the smoothing capacitor 30 that occurs according to the current I₃ are shown. The vertical axes of the currents I₁, I₂, and I₃ show current values [A], and the vertical axis of the capacitor voltage Vdc shows voltage values [V]. The horizontal axes all indicate time t. The controller 60 of the power conversion device 1 controls the operation of the inverter 40 so that the current I₂ shown in FIG. 3 or FIG. 6 flows into the inverter 40. Accordingly, compared to the example in FIG. 2, the frequency component of the current that flows from the rectifier 20 into the smoothing capacitor 30 is reduced, and thus the current I₃ that flows into the smoothing capacitor 30 can be reduced. Specifically, the controller 60 controls the operation of the inverter 40 so that the current I₂, which includes a pulsating current with the frequency component of the current I₁ as its main component, flows into the inverter 40.

The frequency component of the current I₁ is determined on the basis of the frequency of the alternating current supplied from the power source 10 and the configuration of the rectifier 20. For that reason, the controller 60 can set the frequency component of the pulsating current superimposed on the current I₂ to a component with a predetermined amplitude and phase. The frequency component of the pulsating current superimposed on the current I₂ forms a waveform similar to the frequency component of the current I₁. The controller 60 brings the frequency component of the pulsating current superimposed on the current I₂ close to the frequency component of the current I₁ and reduces the current I₃ that flows into the smoothing capacitor 30. This makes it possible to reduce the pulsating voltage generated in the capacitor voltage Vdc as shown in FIG. 6.

The controller 60 controls the pulsation of the current I₂ flowing into the inverter 40 by controlling the operation of the inverter 40, which is the same as controlling the pulsation of the first AC power output from the inverter 40 to the compressor 201. The controller 60 controls the operation of the inverter 40 so that the pulsation in the second AC power output from the inverter 40 is smaller than the pulsation of the power output from the rectifier 20. The controller 60 controls the amplitude and phase of the pulsation in the second AC power output from the inverter 40 so that the voltage ripple of the capacitor voltage Vdc, that is, the voltage ripple generated in the smoothing capacitor 30, is smaller than the voltage ripple generated in the smoothing capacitor 30 for situations where the second AC power output from the inverter 40 does not include pulsation corresponding to the pulsation of the power flowing into the smoothing capacitor 30. Alternatively, the controller 60 controls the amplitude and phase of the pulsation in the second AC power output from the inverter 40 so that the current ripple flowing in and from the smoothing capacitor 30 is smaller than the current ripple generated in the smoothing capacitor 30 for situations where the second AC power output from the inverter 40 does not include pulsation corresponding to the pulsation of the power flowing into the smoothing capacitor 30.

### Advantages of First Embodiment

The peak value of the current I₂ in FIG. 6, which shows the first embodiment, is π/2 times the value of the current I₂ in FIG. 3, which shows a comparative example, and the surge is also π/2 times higher. The first embodiment includes the snubber capacitor 50, thereby suppressing a surge voltage.

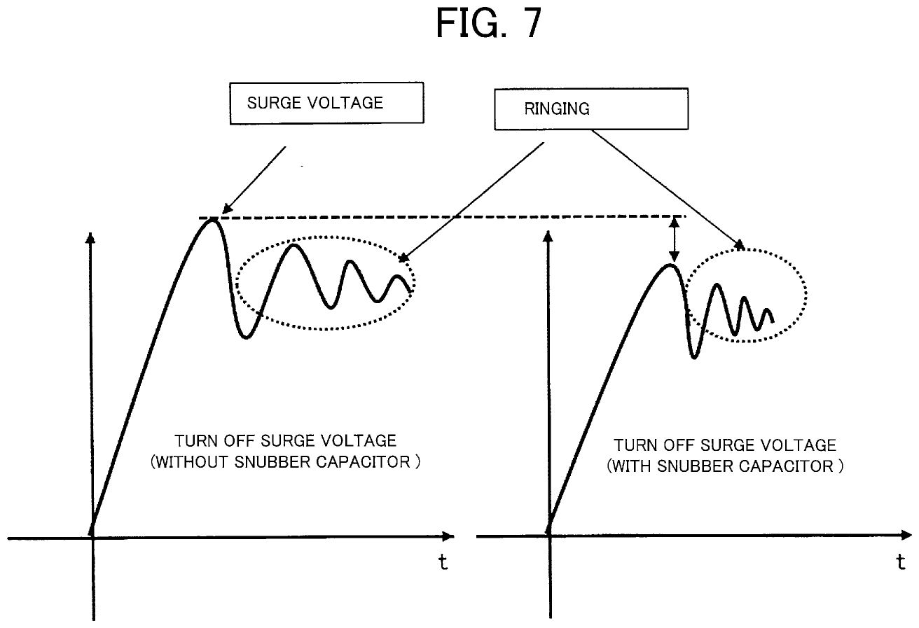

FIG. 7 is a waveform diagram showing the surge voltage in the case of the comparative example (without snubber capacitor) and the surge voltage in the case of the first embodiment (with snubber capacitor). As shown in FIG. 7, by including the snubber capacitor 50, the peak value of the surge voltage is reduced and ringing is suppressed.

### Modification of First Embodiment

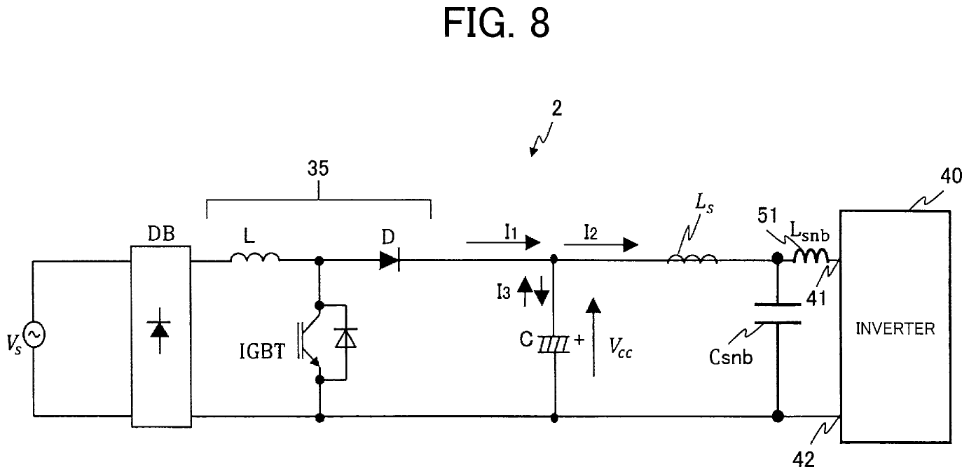

FIG. 8 is a diagram showing an example of the configuration of a power conversion device according to a modification of the first embodiment. In FIG. 8, each component identical or corresponding to a component shown in FIG. 4 is assigned the same reference sign as those in FIG. 4. The power conversion device according to the modification differs from the example shown in FIG. 4 in that the power conversion device includes a booster circuit (i.e., a boost chopper circuit), which is composed of a reactance (L), a diode (D), and a switching element (IGBT), as a power-factor improvement circuit (PFC) 35.

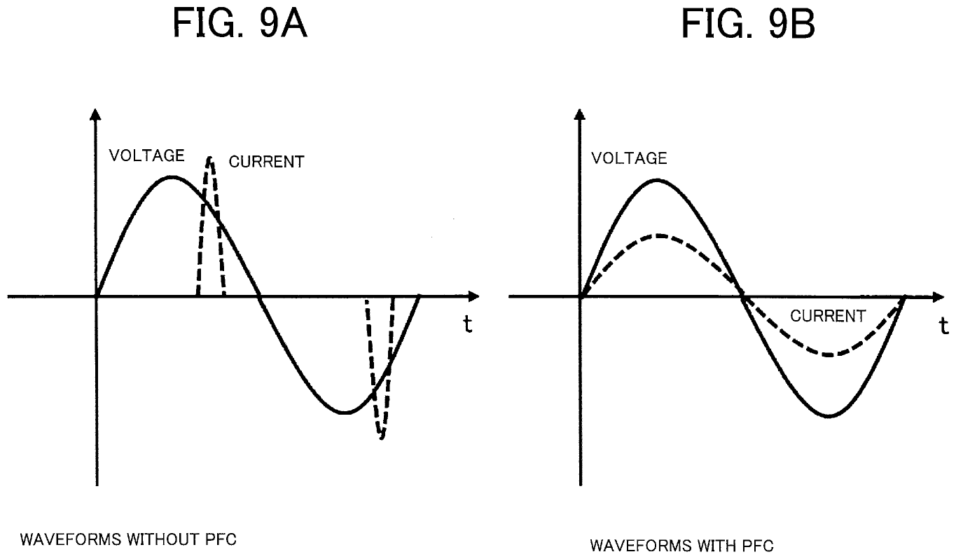

FIG. 9A shows the waveforms for the case without PFC, and FIG. 9B shows the waveforms for the case with PFC. In FIG. 9A, the current is not sinusoidal and there is a phase delay, and thus the power factor is low, but, in contrast, in FIG. 9B, the current is sinusoidal and the phase delay is small, and thus the power factor is high.

### Second Embodiment

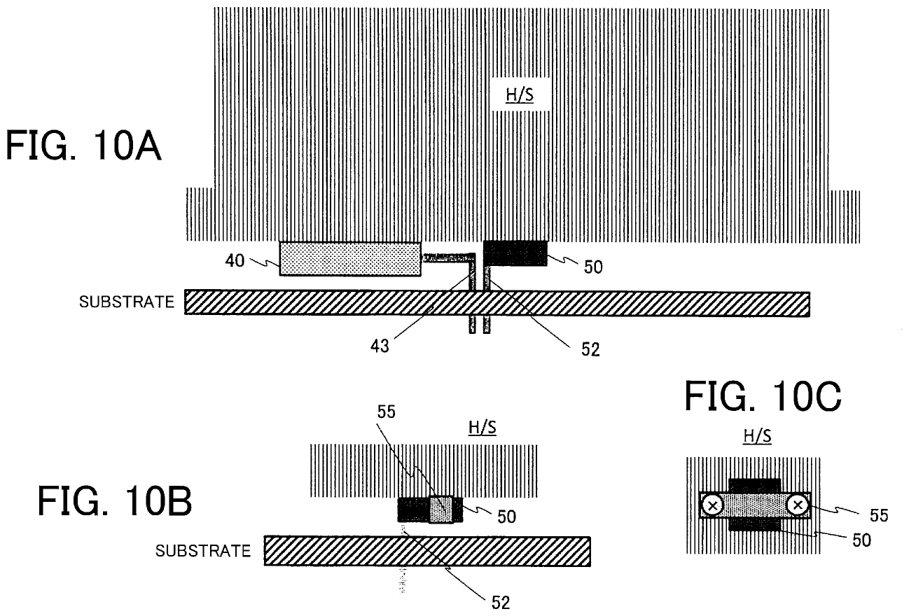

FIG. 10A is a side surface view showing the location of the snubber capacitor 50 of the power conversion device according to a second embodiment. FIG. 10B is a side surface view showing a fixing member 55 for the snubber capacitor 50. FIG. 10C is a front view showing the fixing member 55 for the snubber capacitor 50 (i.e., a view of the device of FIG. 10B from below). The power conversion device according to the second embodiment is the power conversion device 1 or 1a described in the first embodiment.

In the power conversion device according to the second embodiment, the snubber capacitor 50 is disposed in contact with a heat sink H/S as a cooler, as shown in FIG. 10A, and is fixed to the heat sink H/S with the fixing member 55 (e.g., a screw) as shown in FIGS. 10B and 10C. The substrate includes the circuitry of the power conversion device. The inverter 40 is disposed in contact with or near the heat sink H/S. The inverter 40 is connected to the circuitry of the substrate through a lead wire 43. The snubber capacitor 50 is connected to the circuitry of the substrate through a lead wire 52.

Thus, the snubber capacitor 50 is disposed in the air gap between the heat sink and the substrate, and the loop of the circuitry from the smoothing capacitor 30 to the three-phase inverter 40 is reduced, thereby reducing the switching loop of the smoothing capacitor 30 and the inverter 40. As a result, parasitic inductance components are reduced, and thus switching noise can be reduced.

### Third Embodiment

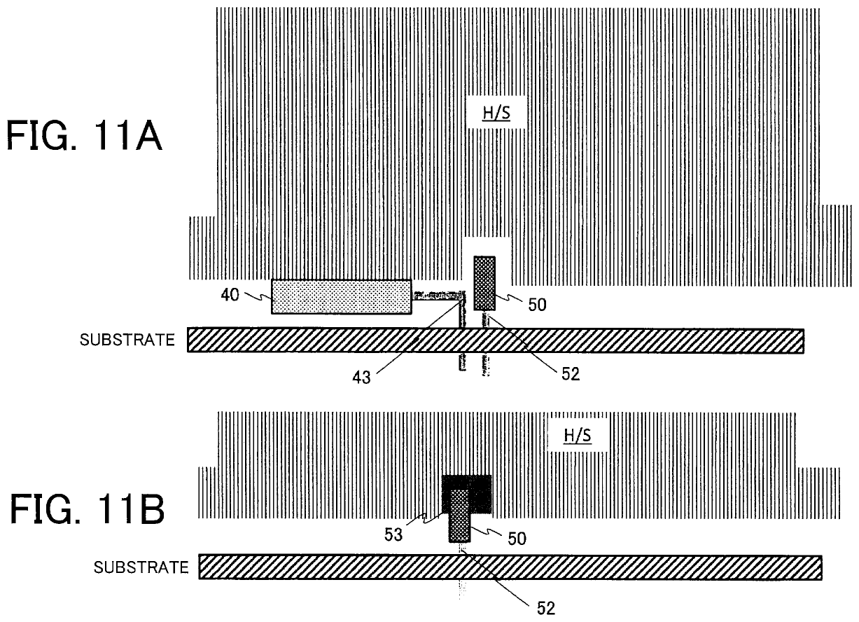

FIG. 11A is a side surface view showing the location of the snubber capacitor 50 of the power conversion device according to a third embodiment, and FIG. 11B is a side view showing a vibration damping member 53 that is a fixing member for the snubber capacitor 50. The power conversion device according to the third embodiment is the power conversion device 1 or 1a described in the first embodiment.

As shown in FIG. 11A, the power conversion device according to the third embodiment includes the heat sink H/S with the depression, at least part of the snubber capacitor 50 is disposed in the depression, and the circuitry on the substrate and the snubber capacitor 50 are connected through the lead wire 52. Also, as shown in FIG. 11B, a vibration damping member (e.g., elastic material, resin, etc.) may be disposed around the snubber capacitor 50 in the depression.

With the power conversion device according to the third embodiment, the contact area between the snubber capacitor 50 and the heat sink can be increased, and thus heat dissipation efficiency can be increased.

### Fourth Embodiment

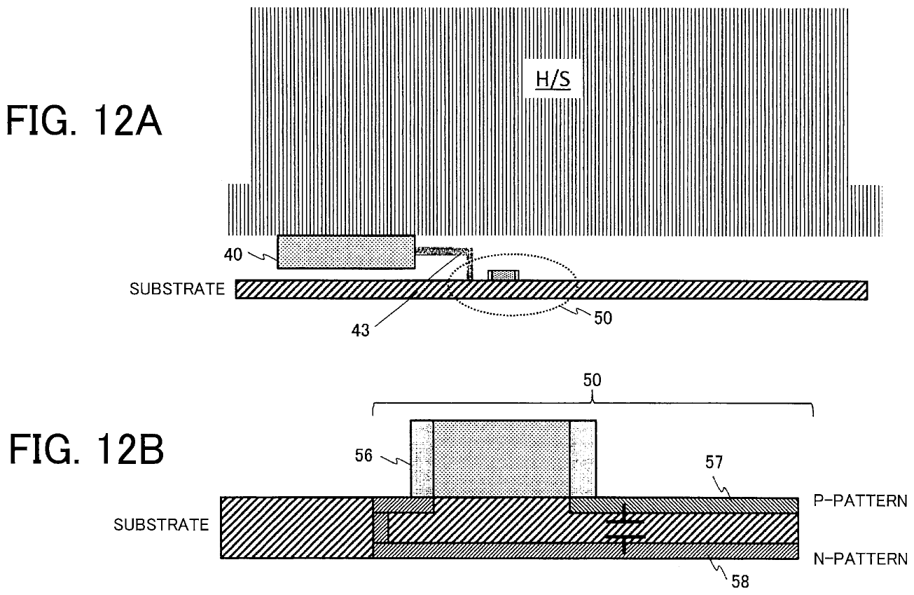

FIG. 12A is a side surface view showing the location of the snubber capacitor of the power conversion device according to a fourth embodiment, and FIG. 12B is a cross-sectional view showing the wiring layer that constitutes part of the snubber capacitor. The power conversion device according to the fourth embodiment is the power conversion device 1 or 2 described in the first embodiment.

In the power conversion device according to the fourth embodiment, the snubber capacitor 50 is formed of the chip capacitor 56 disposed on a substrate, and the first and second wiring 57 and 58 connected to the chip capacitor 56 and disposed on both sides of the substrate, respectively. Therefore, in addition to the electrical capacitance of the chip capacitor, the electrical capacitance between the wiring can be obtained, and the capacitance of the capacitor can be increased.

Also, the snubber capacitor 50 can be disposed in the space between the heat sink and the substrate, thereby simplifying the structure.

### Fifth Embodiment

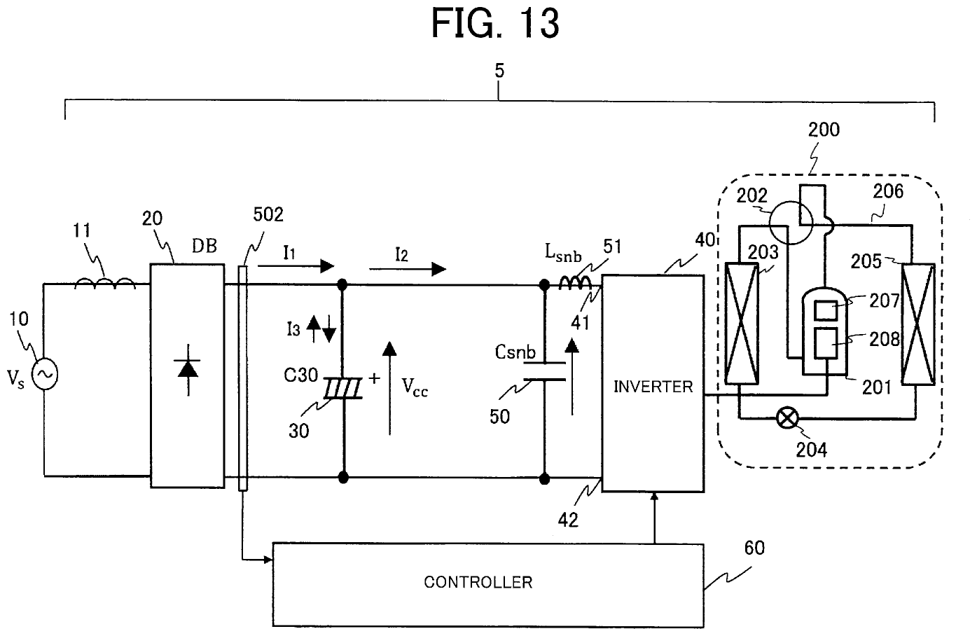

FIG. 13 is a diagram showing the configuration of an air conditioner 5 as refrigeration cycle applied equipment according to a fifth embodiment. The air conditioner 5 includes the power conversion device 1 and a refrigeration cycle device 200. The refrigeration cycle applied equipment is, for example, an air conditioner, a refrigerator, or the like. The power conversion device of the air conditioner 5 can employ the power conversion device described in any of the first to fourth embodiments.

The refrigeration cycle device 200 includes a compressor 201, a four-way valve 202, an indoor heat exchanger 203, an expansion valve 204 as an expansion mechanism, an outdoor heat exchanger 205, and refrigerant piping 206 that connects these components sequentially. Also, a compression mechanism 207 that compresses a refrigerant and an electric motor 208 (e.g., the electric motor 208 in the first to fourth embodiments) that operates the compression mechanism 207 are provided inside the compressor 201. Also, the electric motor 208 is driven by one of the inverters 40 of the power conversion device 1.

In the air conditioner 5 according to the fifth embodiment, circuitry malfunctions due to unexpected open states and short-circuit paths caused by element failures can be prevented at low cost without an increase in the number of components. This makes it obtain the advantages of contributing to energy conservation by reducing losses of the power conversion device 1 and of mitigating global warming.

Each configuration shown in the embodiments described above is an example, and can be combined with another known technology, or with each other. Also, each configuration shown in the embodiments described above can be omitted or changed in part to the extent that it does not depart from the gist.

1. A power conversion device comprising:
rectifier circuitry to rectify a first alternating current supplied from a power source and to output a first current as a rectified current;
a smoothing capacitor connected between output terminals of the rectifier circuitry;
an inverter including input terminals, to convert a second current in the first current into a second alternating current, and to output the second alternating current, the second current being a current inputted to the input terminals;
a snubber capacitor connected between the input terminals at a position in the proximity of the input terminals; and
a controller to control the inverter so that pulsation in AC power output from the inverter is smaller than pulsation of power output from the rectifier circuitry.

2. The power conversion device according to claim 1, wherein when C represents an electrical capacitance [F] of the snubber capacitor, Lₛ represents an inductance [H] of wiring connected to the input terminals, h represents the second current [A], V_{surge} represents a surge voltage [V] of the second current, and V_{cc} represents a voltage [V] at both ends of the smoothing capacitor, the snubber capacitor satisfies
$$C \geq \frac{{π}^{2} * {L}_{s} * {( {I}_{2} )}^{2}}{2 {π}^{2} * {( {V}_{s u r g e} )}^{2} - 8 {V}_{c c}^{2}} .$$

3. The power conversion device according to claim 1, wherein an impedance of first circuitry that is circuitry from one of the input terminals of the inverter through the snubber capacitor to the other input terminal is smaller than an impedance of second circuitry that is circuitry from one of the input terminals of the inverter through the smoothing capacitor to the other input terminal.

4. The power conversion device according to claim 1, further comprising a heatsink,
wherein the snubber capacitor is disposed at a position in the proximity of the heatsink.

5. The power conversion device according to claim 1, further comprising a heatsink,
wherein the snubber capacitor is disposed in contact with the heatsink.

6. The power conversion device according to claim 1, further comprising a heatsink including a depression,
wherein at least a part of the snubber capacitor is disposed in the depression.

7. The power conversion device according to claim 4 wherein the inverter is disposed in contact with the heatsink.

8. The power conversion device according to claim 1, further comprising a substrate,
wherein the snubber capacitor is formed of a chip capacitor disposed on the substrate and first and second wiring disposed on both sides of the substrate respectively, the first and second wiring being connected to the chip capacitor.

9. The power conversion device according to claim 1 wherein the smoothing capacitor is an electrolytic capacitor.

10. The power conversion device according to claim 1, further comprising a power-factor improvement circuit.

11. Refrigeration cycle applied equipment comprising:
the power conversion device according to claim 1; and
a refrigeration cycle device including an electric motor driven by the power conversion device.

12. The power conversion device according to claim 1 wherein the controller controls amplitude and phase of pulsation in the AC power output from the inverter so that a current ripple generated in the smoothing capacitor is smaller than a current ripple generated in the smoothing capacitor for situations where the AC power output from the inverter does not include pulsation corresponding to pulsation of power flowing into the smoothing capacitor.
